(19) United States
(12) Patent Application Publication
(10) Pub. No.: US 2024/0170530 A1
(43) Pub. Date: May 23, 2024

(54) INTEGRATED CIRCUIT DEVICE AND METHOD OF MANUFACTURING THE SAME

(71) Applicant: SAMSUNG ELECTRONICS CO., LTD., Suwon-si (KR)

(72) Inventors: Ingyu BAEK, Suwon-si (KR); Changyong UM, Suwon-si (KR); Kwansik KIM, Suwon-si (KR); Jungsan KIM, Suwon-si (KR); Taemin KIM, Suwon-si (KR)

(73) Assignee: SAMSUNG ELECTRONICS CO. LTD., Suwon-si (KR)

(21) Appl. No.: 18/387,702

(22) Filed: Nov. 7, 2023

(30) Foreign Application Priority Data
Nov. 23, 2022 (KR) 10-2022-0158530

(51) Int. Cl. H01G 15/00; H01L 23/522; H01L 23/528; H01L 27/06

(52) U.S. Cl. CPC H01L 28/75; H01L 23/5226; H01L 23/5283; H01L 27/0629; H01L 28/90

(57) ABSTRACT

An integrated circuit device, including a substrate; a lower insulating film; and a capacitor structure including: a plurality of first conductive patterns sequentially stacked on the lower insulating film; a plurality of second conductive patterns on the plurality of first conductive patterns; a first via at a first side of the capacitor structure, wherein the first via physically contacts and is electrically connected to the plurality of first conductive patterns, and is not electrically connected to the plurality of second conductive patterns; and a second via at a second side of the capacitor structure, wherein the second via physically contacts and is electrically connected to the plurality of second conductive patterns, and is not electrically connected to the plurality of first conductive patterns.

### CROSS-REFERENCE TO RELATED APPLICATION

This application is based on and claims priority under 35 U.S.C. § 119 to Korean Patent Application No. 10-2022-0158530, filed on Nov. 23, 2022, in the Korean Intellectual Property Office, the disclosure of which is incorporated by reference herein in its entirety.

### BACKGROUND

### 1. Field

The disclosure relates to an integrated circuit device, and more particularly, to an integrated circuit device including a capacitor structure.

### 2. Description of Related Art

Because of characteristics, such as compactness, multifunctionalization, and/or low manufacturing cost, semiconductor devices are widely used in the electronics industry. However, with the development of the electronics industry, semiconductor devices are becoming highly integrated which may cause many problems. For example, because of the high integration density of semiconductor devices, the critical dimension and/or spacing of patterns in semiconductor devices may be decreased while the height and/or aspect ratio of the patterns may increase. This may cause an increase in variations in vapor deposition processes and/or etching processes of thin films, which may cause the reliability of semiconductor devices may be reduced.

### SUMMARY

Provided is an integrated circuit device having increased performance and integration density by implementing a high-capacity capacitor.

Also provided is a method of manufacturing an integrated circuit device, by which conductive layers and dielectric layers are etched using a single mask.

Additional aspects will be set forth in part in the description which follows and, in part, will be apparent from the description, or may be learned by practice of the presented embodiments.

In accordance with an aspect of the disclosure, an integrated circuit device includes a substrate; a lower insulating film on the substrate, the lower insulating film comprising a device; and a capacitor structure on the lower insulating film, wherein the capacitor structure includes: a plurality of first conductive patterns sequentially stacked on the lower insulating film and spaced apart from each other; a plurality of second conductive patterns on the plurality of first conductive patterns and spaced apart from each other, wherein each second conductive pattern of the plurality of second conductive patterns is on a corresponding first conductive pattern of the plurality of first conductive patterns; a first via at a first side of the capacitor structure, wherein the first via physically contacts and is electrically connected to the plurality of first conductive patterns, and is not electrically connected to the plurality of second conductive patterns; and a second via at a second side of the capacitor structure, wherein the second side is opposite to the first side and faces the first side, and wherein the second via physically contacts and is electrically connected to the plurality of second conductive patterns, and is not electrically connected to the plurality of first conductive patterns.

In accordance with an aspect of the disclosure, an integrated circuit device includes a substrate; a lower insulating film on the substrate, the lower insulating film comprising a device; and a capacitor structure on the lower insulating film, wherein the capacitor structure comprises: a first conductive pattern on the lower insulating film; a second conductive pattern on the first conductive pattern; a third conductive pattern on the second conductive pattern; a fourth conductive pattern on the third conductive pattern; a first via at a first side of the capacitor structure, wherein the first via being physically contacts and is electrically connected to the first conductive pattern and the third conductive pattern, and is not electrically connected to the second conductive pattern and the fourth conductive pattern; and a second via at a second side of the capacitor structure, wherein the second side is opposite to the first side and faces the first side, and wherein the second via physically contacts and is electrically connected to the second conductive pattern and the fourth conductive pattern and is not electrically connected to the first conductive pattern and the third conductive pattern.

In accordance with an aspect of the disclosure, an integrated circuit device includes a substrate; a lower insulating film on the substrate, the lower insulating film comprising a device; and a capacitor structure on the lower insulating film, wherein the capacitor structure includes: a plurality of first conductive patterns sequentially stacked on the lower insulating film and spaced apart from each other; a plurality of second conductive patterns on the plurality of first conductive patterns and spaced apart from each other, wherein each second conductive pattern of the plurality of second conductive patterns is on a corresponding first conductive pattern of the plurality of first conductive patterns; a first via at a first side of the capacitor structure, wherein the first via physically contacts and is electrically connected to the plurality of first conductive patterns, and does not physically contact and is insulated from the plurality of second conductive patterns; and a second via at a second side of the capacitor structure, wherein the second side is opposite to the first side and faces the first, and wherein the second via physically contacts and is electrically connected to the plurality of second conductive patterns, and does not physically contact and is insulated from the plurality of first conductive patterns, wherein a horizontal cross-sectional area of each of the first via and the second via non-linearly decreases in a direction toward the substrate, wherein a first side wall of each of the first via and the second via faces the plurality of first conductive patterns and the plurality of second conductive patterns and has a stair shape, wherein a second side wall of each of the first via and the second via declines in a direction toward the plurality of first conductive patterns and the plurality of second conductive patterns, and wherein the second side wall is opposite to the first side wall and faces away from the first side wall.

### BRIEF DESCRIPTION OF THE DRAWINGS

The above and other aspects, features, and advantages of certain embodiments of the present disclosure will be more apparent from the following detailed description taken in conjunction with the accompanying drawings in which.

FIG. 1 is a plan view of an integrated circuit device according to an embodiment:

FIG. 2 is a cross-sectional view taken along line C-C′ in FIG. 1 according to an embodiment;

FIGS. 3 to 9 are cross-sectional views of stages in a method of manufacturing the integrated circuit device of FIG. 2 according to embodiments;

FIG. 10A is a plan view of an integrated circuit device according to an embodiment;

FIG. 10B is a cross-sectional view taken along line D-D′ in FIG. 10A and FIG. 10C is a cross-sectional view taken along line E-E′ in FIG. 10A according to an embodiment; and

FIGS. 11A to 17C are cross-sectional views of some stages in a method of manufacturing the integrated circuit device of FIG. 10A to 10C according to embodiments.

### DETAILED DESCRIPTION OF THE EMBODIMENTS

Hereinafter, embodiments are described in detail with reference to the accompanying drawings. However, the disclosure should not be construed as being limited to the embodiments and may be embodied in other various forms. The embodiments are provided to assist in conveying the scope of the disclosure to those skilled in the art. And in the specification description below, “insulated” may mean being not electrically connected.

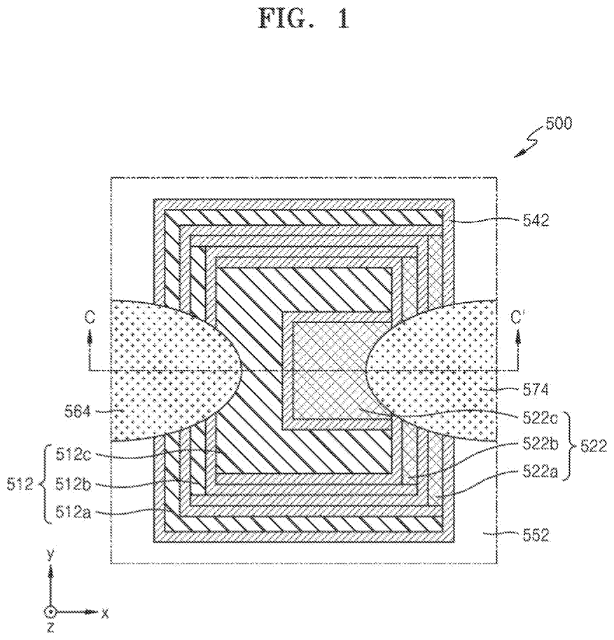

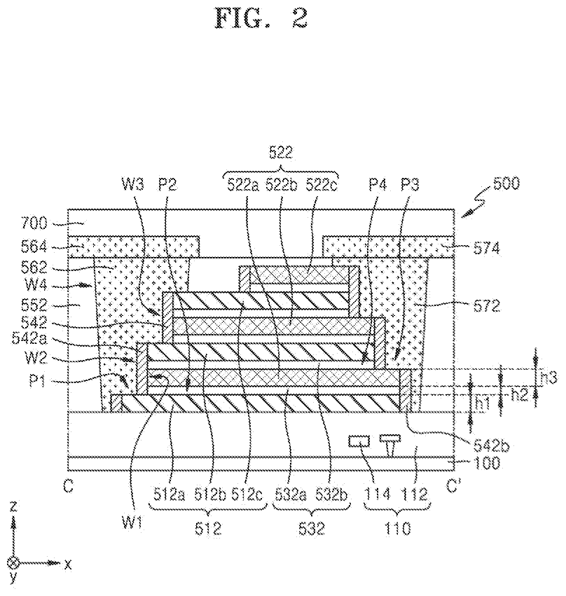

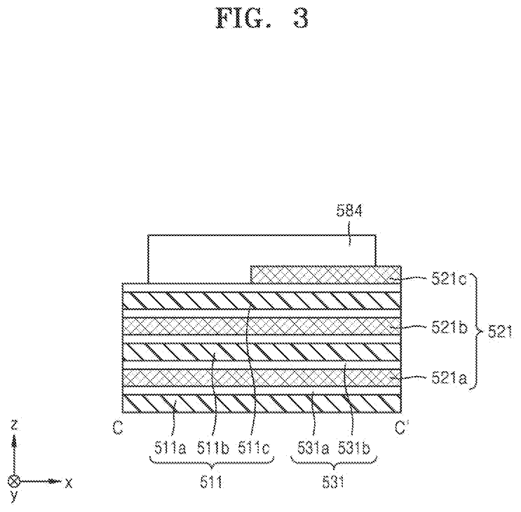

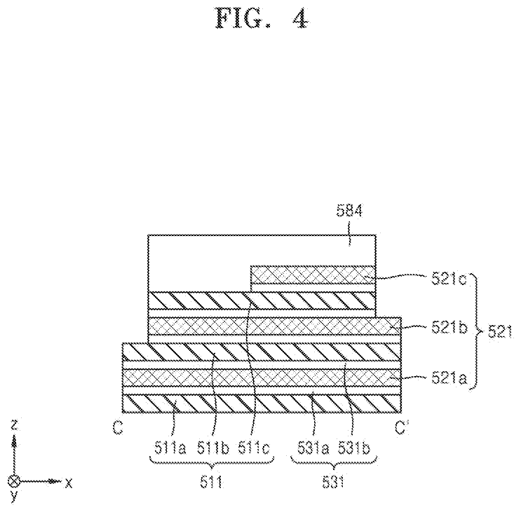

FIG. 1 is a plan view of an integrated circuit device 10 according to an embodiment. FIG. 2 is a cross-sectional view taken along line C-C′ in FIG. 1.

Referring to FIG. 1, a first direction (e.g., the x-direction) and a second direction (e.g., the y-direction) may be horizontal directions that cross each other. For example, the first direction (e.g., the x-direction) may be perpendicular to the second direction (e.g., the y-direction). A third direction (e.g., the z-direction) may cross both the first direction (e.g., the x-direction) and the second direction (e.g., the y-direction). For example, the third direction (e.g., the z-direction) may be perpendicular to the first direction (e.g., the x-direction) and the second direction (e.g., the y-direction). Accordingly, the first direction (e.g., the x-direction), the second direction (e.g., the y-direction), and the third direction (e.g., the z-direction) may be orthogonal to one another.

Referring to FIGS. 1 and 2, a capacitor structure 500 may be on a substrate 100. In embodiments, the integrated circuit device 10 may include a front-end-of-line (FEOL) structure 110 between the substrate 100 and the capacitor structure 500. The FEOL structure 110 may include various kinds of individual devices 114 and a lower insulating film 112. The individual devices 114 may include various microelectronic devices, e.g., a metal-oxide-semiconductor field effect transistor (MOSFET), a system large scale integration (LSI), an image sensor such as a complementary metal-oxide-semiconductor (CMOS) image sensor (CIS), a micro-electro-mechanical system (MEMS), an active element, and a passive element. The individual devices 114 may be electrically connected to a conductive region of the substrate 100. Each of the individual devices 114 may be electrically isolated from other individual devices by the lower insulating film 112.

In some embodiments, the lower insulating film 112 may include a silicon oxide-based material. For example, the lower insulating film 112 may include plasma enhanced oxide (PEOX), tetraethyl orthosilicate (TEOS), boro TEOS (BTEOS), phosphorous TEOS (PTEOS), boro phospho TESO (BPTEOS), boro silicate glass (BSG), phospho silicate glass (PSG), or boro phospho silicate glass (BPSG). In some embodiments, the lower insulating film 112 may include a low-k film, e.g., an SiOC film or an SiCOH film, which has a low dielectric constant K of about 2.2 to about 3.0.

According to an embodiment, the capacitor structure 500 may be formed in an interlayer insulating film 552. The interlayer insulating film 552 may cover a portion of the capacitor structure 500.

The capacitor structure 500 may include a plurality of first conductive patterns 512, which are separated from each other on the lower insulating film 112, and a plurality of second conductive patterns 522, which are on the first conductive patterns 512, respectively, and separated from each other. The level of a voltage applied to the first conductive patterns 512 may be different from the level of a voltage applied to the second conductive patterns 522. The capacitor structure 500 may store charges in a plurality of dielectric films 532 by using potential differences between the first conductive patterns 512 and the second conductive patterns 522.

The first conductive patterns 512 may include a lower first conductive pattern 512a, an intermediate first conductive pattern 512b, and an upper first conductive pattern 512c. The area of the top surface of each of the first conductive patterns 512 may increase toward the substrate 100. For example, the area of the top surface of the intermediate first conductive pattern 512b may be greater than the area of the top surface of the upper first conductive pattern 512c, and the area of the top surface of the lower first conductive pattern 512a may be greater than the area of the top surface of the intermediate first conductive pattern 512b. The second conductive patterns 522 may include a lower second conductive pattern 522a, an intermediate second conductive pattern 522b, and an upper second conductive pattern 522c. The area of the top surface of each of the second conductive patterns 522 may increase toward the substrate 100. For example, the area of the top surface of the intermediate second conductive pattern 522b may be greater than the area of the top surface of the upper second conductive pattern 522c, and the area of the top surface of the lower second conductive pattern 522a may be greater than the area of the top surface of the intermediate second conductive pattern 522b.

For example, each of the first conductive patterns 512 and the second conductive patterns 522 may include at least one of cobalt (Co), titanium (Ti), nickel (Ni), tungsten (W), molybdenum (Mo), a titanium nitride (TiN) film, a titanium silicon nitride (TiSiN) film, a titanium aluminum nitride (TiAlN) film, a tantalum nitride (TaN) film, a tantalum silicon nitride (TaSiN) film, a tantalum aluminum nitride (TaAlN) film, a tungsten nitride film (WN) film, and a combination thereof, but is not limited thereto.

The capacitor structure 500 may further include a dielectric film 532 between one of the first conductive patterns 512 and one of the second conductive patterns 522. For example, a first dielectric film 532a may be between the top surface of a first conductive pattern 512 and the bottom surface of a second conductive pattern 522. In embodiments, the first dielectric film 532a may extend along the top surface of the first conductive pattern 512 and cover the first conductive pattern 512. As another example, a second dielectric film 532b may be between the top surface of a second conductive pattern 522 and the bottom surface of a first conductive pattern 512. In embodiments, the second dielectric film 532b may extend along the top surface of the second conductive pattern 522. For example, the dielectric film 532 may include at least one of silicon nitride, silicon oxide, and a combination thereof, but is not limited thereto. For example, the dielectric film 532 may include a high-k material that has a higher permittivity than silicon oxide.

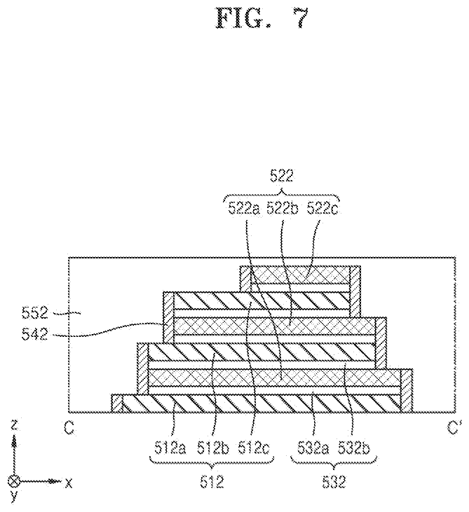

According to an embodiment, the area of the top surface of the dielectric film 532 may be substantially the same as the area of the bottom surface of one of the first conductive patterns 512 which is on the dielectric film 532, or one of the second conductive patterns 522 which is on the dielectric film 532. For example, as shown in FIG. 2 and FIG. 7, the area of the top surface of the first dielectric film 532a may be substantially the same as the area of the bottom surface of the lower second conductive pattern 522a on the first dielectric film 532a. The area of the top surface of the second dielectric film 532b may be substantially the same as the area of the bottom surface of the intermediate first conductive pattern 512b on the second dielectric film 532b. Because the area of the top surface of the dielectric film 532 is substantially the same as the area of the bottom surface of each of the first and second conductive patterns 512 and 522, which is on the dielectric film 532, the dielectric film 532 may be not exposed to the outside.

According to an embodiment, a thickness h1 of each of the first conductive patterns 512 and a thickness h3 of each of the second conductive patterns 522 may be greater than a thickness h2 of the dielectric film 532.

The capacitor structure 500 may include a first via 562 at a side thereof. The first via 562 may extend through the interlayer insulating film 552 in the third direction (e.g., the z-direction) that is perpendicular to the top surface of the lower insulating film 112. As shown in FIG. 2 and FIG. 5, the capacitor structure 500 may have a pyramid shape that has a width decreasing upwards, for example decreasing in a direction from the substrate 100 toward the upper insulating film 700. In embodiments, the first via 562 may be on a side of the pyramid shape of the capacitor structure 500. The capacitor structure 500 may include a second via 572 at an opposite side to the side in which the first via 562 is provided. The second via 572 may extend through the interlayer insulating film 552 in the third direction (e.g., the z-direction) that is perpendicular to the top surface of the lower insulating film 112.

The first via 562 may be electrically connected to the first conductive patterns 512 and insulated from the second conductive patterns 522. For example, at least a portion of the top surface of each of the first conductive patterns 512 may be not in contact with the dielectric film 532. For example, the lower first conductive pattern 512a may include a first portion P1, which is in contact with the first via 562, and a second portion P2, which is in contact with the first dielectric film 532a, on the top surface thereof. In embodiments, the lower first conductive pattern 512a may be electrically connected to the first via 562 through the first portion P1 thereof. The first dielectric film 532a may extend along the top surface of the lower first conductive pattern 512a. A side of the first dielectric film 532a, which is near the second via 572, may be on the same vertical line as a side of the lower first conductive pattern 512a, which is near the second via 572. Accordingly, the top surface of the lower first conductive pattern 512a may be not in contact with the second via 572 and may thus be insulated from the second via 572. The other first conductive patterns 512 may be similarly electrically connected to the first via 562 and insulated from the second via 572. For example, a portion of the intermediate first conductive pattern 512b may be in contact with the first via 562, and the intermediate first conductive pattern 512b may be insulated from the second via 572 by the second dielectric film 532b. As a result, the first via 562 may be in contact with at least a portion of the top surface of each of the first conductive patterns 512.

The second via 572 may be electrically connected to the second conductive patterns 522 and insulated from the first conductive patterns 512. For example, at least a portion of the top surface of each of the second conductive patterns 522 may be not in contact with the dielectric film 532. For example, the lower second conductive pattern 522a may include a third portion P3, which is in contact with the second via 572, and a fourth portion P4, which is in contact with the second dielectric film 532b, on the top surface thereof. In embodiments, the lower second conductive pattern 522a may be electrically connected to the second via 572 through the third portion P3 thereof. The second dielectric film 532b may extend along the top surface of the lower second conductive pattern 522a. A side of the second dielectric film 532b, which is near the first via 562, may be on the same vertical line as a side of the lower second conductive pattern 522a, which is near the first via 562. Accordingly, the top surface of the lower second conductive pattern 522a may be not in contact with the first via 562 and may thus be insulated from the first via 562. The other second conductive patterns 522 may be similarly electrically connected to the second via 572 and insulated from the first via 562. For example, a portion of the intermediate first second pattern 522b may be in contact with the second via 572, and the intermediate second conductive pattern 522b may be insulated from the first via 562 by a dielectric film 532. As a result, the second via 572 may be in contact with at least a portion of the top surface of each of the second conductive patterns 522.

According to an embodiment, the bottommost surface of the first via 562 may be at the same vertical level, for example a same level in the third direction (e.g., the z-direction), as the bottommost surface of the second via 572. In embodiments, the vertical level of the bottommost surfaces of the first via 562 and the second via 572 may be substantially the same as the vertical level of the topmost surface of the lower insulating film 112 or the vertical level of the bottom surface of the lower first conductive pattern 512a.

Accordingly, as described above, the integrated circuit device 10 may include the capacitor structure 500, which includes the first conductive patterns 512 and the second conductive patterns 522 alternatingly stacked on the lower insulating film 112. The capacitor structure 500 may store a high capacity of charge in a limited space by including the first and second conductive patterns 512 and 522 that are alternatingly stacked.

According to an embodiment, the first conductive patterns 512 may be electrically connected to one first via 562, and the second conductive patterns 522 may be electrically connected to one second via 572. Because the first conductive patterns 512 may be electrically connected to one another by the first via 562 and not by separate vias, and the second conductive patterns 522 may be electrically connected to one another by the second via 572 and not by separate vias, each conductive pattern may quickly and efficiently transmit electrical signals to another element.

As shown in FIG. 2, a side wall W3 of each of the first via 562 and the second via 572, which faces the first and second conductive patterns 512 and 522, may have a stair shape. For example, the side wall W3 of each of the first via 562 and the second via 572 may include a horizontal surface, which is in contact with one of the first conductive patterns 512 or one of the second conductive patterns 522, and a vertical surface, which is in contact with a side wall of one of a plurality of insulating spacers 542. An opposite side wall W4 facing away from the side wall W3 may decline toward the first and second conductive patterns 512 and 522. The horizontal cross-sectional area of each of the first via 562 and the second via 572 may non-linearly decrease toward the substrate 100. For example, the horizontal cross-sectional area of each of the first via 562 and the second via 572 at the same vertical level as the top surface of each of the first and second conductive patterns 512 and 522 may rapidly decrease toward the substrate 100.

A first wiring 564 may be on the interlayer insulating film 552, and a second wiring 574 may be spaced horizontally apart from the first wiring 564. The first wiring 564 may cover a portion of the interlayer insulating film 552 and may be electrically connected to the first via 562. The second wiring 574 may cover a portion of the interlayer insulating film 552 and may be electrically connected to the second via 572. The first wiring 564 may overlap with a portion of each of the first conductive patterns 512, and the second wiring 574 may overlap with a portion of each of the second conductive patterns 522. The first wiring 564 may horizontally extend on the first via 562, may be in communication with, or otherwise connected to, the first via 562, and may have a wider horizontal cross-sectional area than the first via 562. The second wiring 574 may horizontally extend on the second via 572, may be in communication with, or otherwise connected to, the second via 572, and may have a wider horizontal cross-sectional area than the second via 572.

According to an embodiment, the capacitor structure 500 may include a plurality of insulating spacers 542 surrounding, covering, or in contact with the side walls of the first conductive patterns 512 and the side walls of the second conductive patterns 522. A side wall of each of the insulating spacers 542 may be in contact with at least one of the first conductive patterns 512 and the second conductive patterns 522. An opposite side wall of each of the insulating spacers 542, which faces away from the side wall discussed above, may be in contact with the first via 562 or the second via 572. For example, as shown in FIG. 2, a first side wall W1 of a first insulating spacer 542a may be in contact with a side wall of the first dielectric film 532a, a side wall of the lower second conductive pattern 522a, a side wall of the second dielectric film 532b, and a side wall of the intermediate first conductive pattern 512b. A second side wall W2 of the insulating spacer 542a, which faces opposite to the first side wall W1 thereof, may be in contact with the first via 562. In a similar manner, each of the insulating spacers 542 may be in contact with first and second conductive patterns 512 and 522, dielectric layers 532, and one of the first and second vias 562 and 572. Because the insulating spacers 542 may be formed to surround the side walls of the first conductive patterns 512 and the side walls of the second conductive patterns 522, the first conductive patterns 512 may be insulated from the second via 572, and the second conductive patterns 522 may be insulated from the first via 562. The insulating spacers 542 may include silicon nitride or silicon oxide but is not necessarily limited thereto.

According to an embodiment, the insulating spacers 542 may include the first insulating spacer 542a in contact with the first via 562 and a second insulating spacer 542b in contact with the second via 572. The top surface of the first insulating spacer 542a may be at a different level than the top surface of the second insulating spacer 542b.

An upper insulating film 700 may be on the interlayer insulating film 552. Although not shown, other elements may be formed in the upper insulating film 700 and electrically connected to the capacitor structure 500.

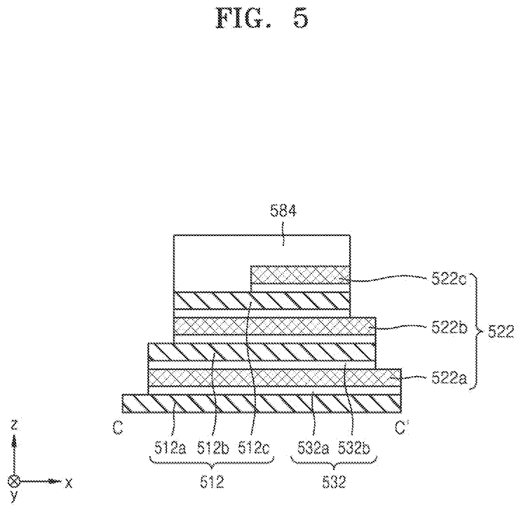

FIGS. 3 to 9 are cross-sectional views of stages in a method of manufacturing the integrated circuit device 10 of FIG. 2. For example, FIGS. 3 to 9 are cross-sectional views taken along the line C-C′ in FIG. 1.

Referring to FIG. 3, a plurality of first conductive layers 511 may be spaced apart from each other in the third direction (e.g., the z-direction). A plurality of second conductive layers 521 may be respectively on the first conductive layers 511 and may be spaced apart from each other in the third direction (e.g., the z-direction). Each of a plurality of dielectric layers 531 may be on one of the first conductive layers 511 or one of the second conductive layers 521. For example, a first dielectric layer 531a may be between the top surface of a lower first conductive layer 511a and the bottom surface of a lower second conductive layer 521a, and a second dielectric layer 531b may be between the top surface of the lower second conductive layer 521a and the bottom surface of an intermediate first conductive layer 511b. A width in the first direction (e.g., the x-direction) of each of the first conductive layers 511 may be substantially the same as a width in the first direction (e.g., the x-direction) of each of the dielectric layers 531. A width in the first direction (e.g., the x-direction) of each of the lower second conductive layer 521a and an intermediate second conductive layer 521b may be substantially the same as the width in the first direction (e.g., the x-direction) of each of the dielectric layers 531. However, a width in the first direction (e.g., the x-direction) of an upper second conductive layer 521c may be less than the width in the first direction (e.g., the x-direction) of each of the dielectric layers 531. Accordingly, a portion of the top surface of a topmost dielectric layer 531 may be exposed to the outside.

A mask 584 may be disposed on the topmost dielectric layer 531 and the upper second conductive layer 521c. A width in the first direction (e.g., the x-direction) of the mask 584 may be less than the width in the first direction (e.g., the x-direction) of each of the dielectric layers 531. For example, the mask 584 may be disposed such that a portion of the top surface of the topmost dielectric layer 531 and a portion of the top surface of the upper second conductive layer 521c are exposed. The mask 584 may include a material that has an etch selectivity with respect to the first conductive layers 511, the second conductive layers 521, and the dielectric layers 531.

Referring to FIG. 4, each of an upper first conductive layer 511c, the upper second conductive layer 521c, the intermediate second conductive layer 521b, and a plurality of dielectric layers 531 may be partially etched by using the mask 584. An etch selectivity used in a process of etching the upper first conductive layer 511c may be different from that used in a process of etching the dielectric layers 531. An etch selectivity used in a process of etching the upper first conductive layer 511c may be the same as that used in a process of etching the intermediate second conductive layer 521b and the upper second conductive layer 521c.

Referring to FIG. 5, a portion of the mask 584 may be etched. In embodiments, the mask 584 may include a material that has a different etch selectivity than the first conductive layers 511 and the second conductive layers 521. After an edge portion of the mask 584 is partially etched, the dielectric layers 531, the first conductive layers 511, and the second conductive layers 521 may be newly etched. For example, after an edge portion of the mask 584 is partially etched, newly exposed portions of the dielectric layers 531, the first conductive layers 511, and the second conductive layers 521 may be etched. When the etching of the first conductive layers 511, the second conductive layers 521, and the dielectric layers 531 is completed, a plurality of first conductive patterns 512, a plurality of second conductive patterns 522, and a plurality of dielectric films 532 may be formed. Consequently, a series of processes of etching the first and second conductive layers 511 and 522 may be performed by partially etching an edge portion of a mask, without using different masks for the series of processes. Accordingly, an etching process may be efficiently performed.

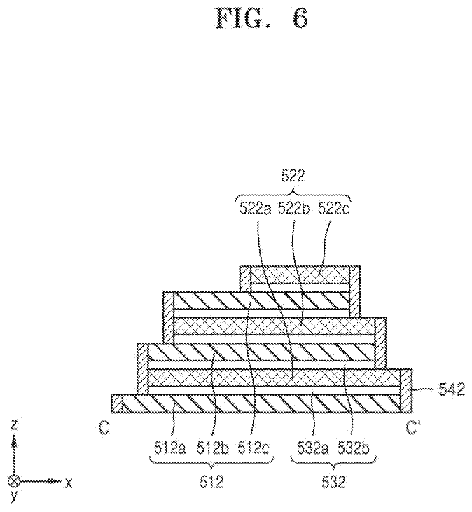

Referring to FIGS. 6 to 9, after the mask 584 is removed, the insulating spacers 542 may be formed on the side walls of the first conductive patterns 512, the second conductive patterns 522, and the dielectric film 532. When the insulating spacers 542 are formed on the side walls of the first conductive patterns 512, the second conductive patterns 522, and the dielectric film 532, only a portion of each of the first conductive patterns 512 and the second conductive patterns 522 may be exposed.

As shown in FIG. 7, after the insulating spacers 542 are formed, the interlayer insulating film 552 may be formed to cover the first conductive patterns 512, the second conductive patterns 522, and the insulating spacers 542.

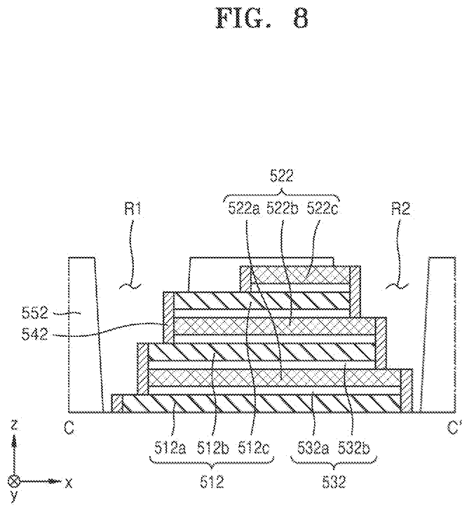

As shown in FIG. 8, after the interlayer insulating film 552 is formed, a plurality of recesses, e.g., a first recess R1 and a second recess R2, may be formed in the interlayer insulating film 552. A portion of the top surface of each of the first conductive patterns 512 may be exposed by the first recess R1. A portion of the top surface of each of the second conductive patterns 522 may be exposed by the second recess R2.

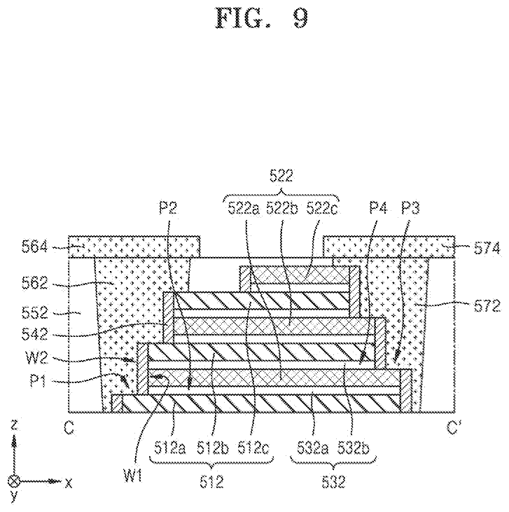

As shown in FIG. 9, a plurality of vias may be formed in the first and second recesses. For example, first via 562 may be formed in the first recess R1, and the second via 572 may be formed in the second recess R2. The first via 562 may be in contact with a portion of the top surface of each of the first conductive patterns 512 and electrically connected to the first conductive patterns 512. The second via 572 may be in contact with a portion of the top surface of each of the second conductive patterns 522 and electrically connected to the second conductive patterns 522. Thereafter, the first wiring 564 may be formed on the top surface of the first via 562, and the second wiring 574 may be formed on the top surface of the second via 572.

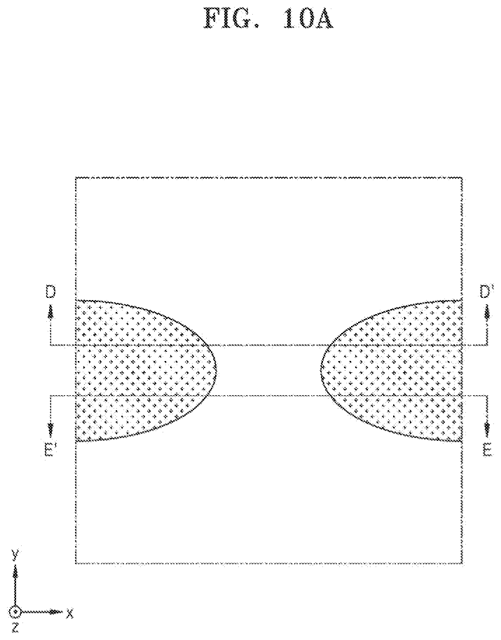

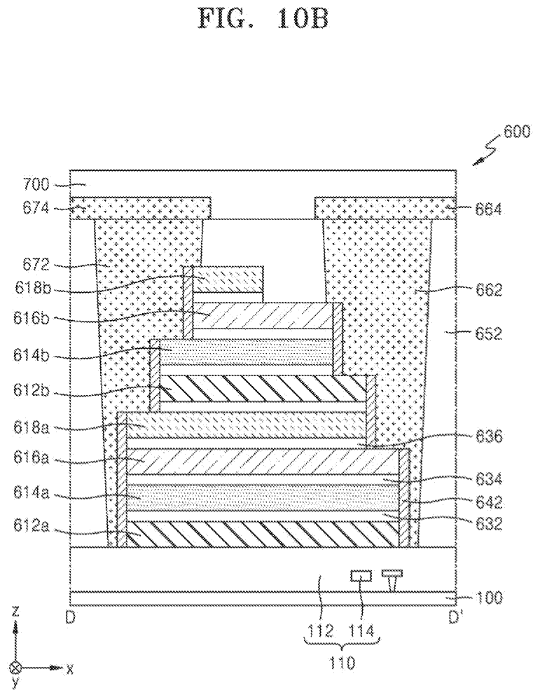

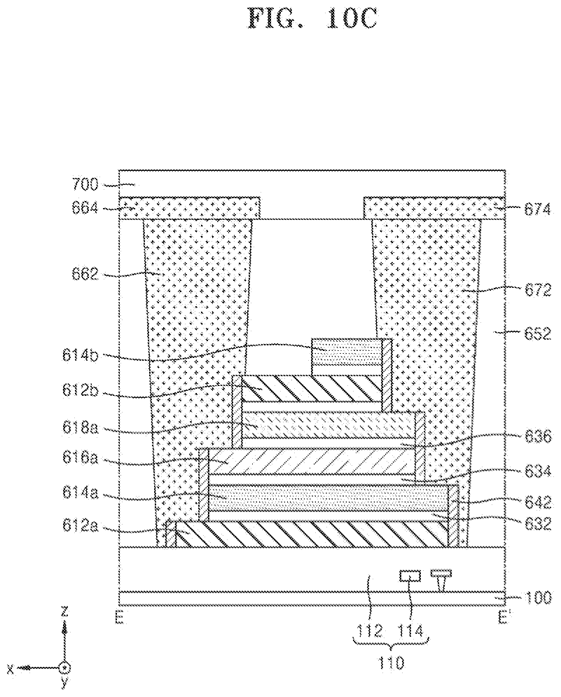

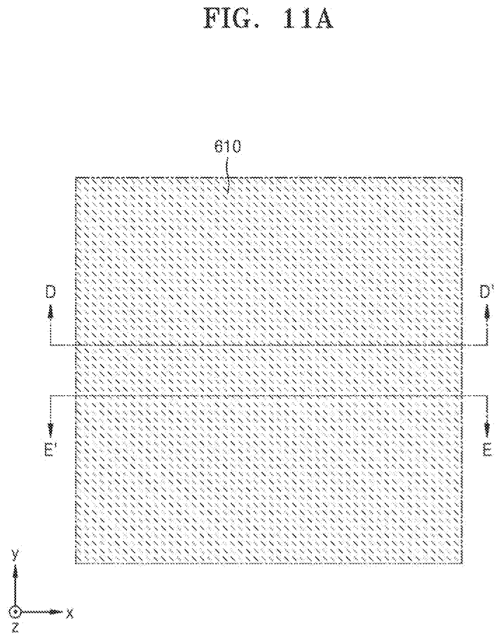

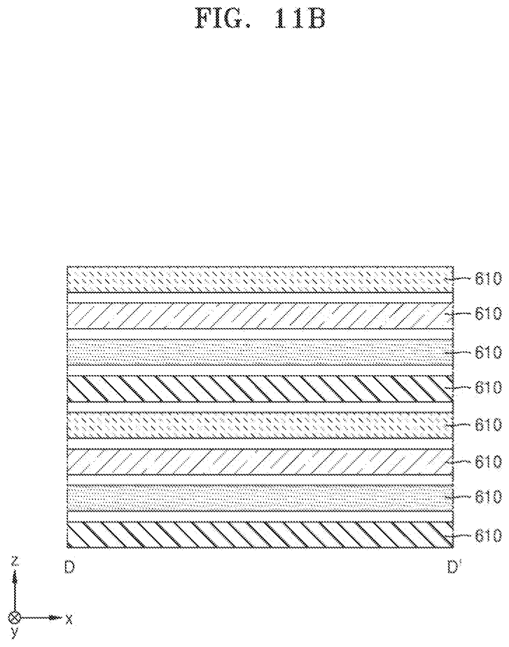

FIG. 10A is a plan view of an integrated circuit device 20 according to an embodiment. FIG. 10B is a cross-sectional view taken along line D-D′ in FIG. 10A. FIG. 10C is a cross-sectional view taken along line E-E′ in FIG. 10A.

Descriptions are given with reference to FIGS. 10A to 10C below. A capacitor structure 600 may be on the substrate 100. In embodiments, the integrated circuit device 20 may include the FEOL structure 110 between the substrate 100 and the capacitor structure 600. The substrate 100 and the FEOL structure 110 in FIGS. 10B and 10C are substantially the same as those described with reference to FIG. 2, and thus, redundant or duplicative descriptions thereof may be omitted.

The capacitor structure 600 may be formed in an interlayer insulating film 652 on the substrate 100. The interlayer insulating film 652 may cover a portion of the capacitor structure 600.

The capacitor structure 600 may include a first conductive pattern 612a on the lower insulating film 112, a second conductive pattern 614a on the first conductive pattern 612a, a third conductive pattern 616a on the second conductive pattern 614a, and a fourth conductive pattern 618a on the third conductive pattern 616a. The level of a voltage applied to the first conductive pattern 612a may be the same as the level of a voltage applied to the third conductive pattern 616a. The level of a voltage applied to the second conductive pattern 614a may be the same as the level of a voltage applied to the fourth conductive pattern 618a. The level of a voltage applied to the first conductive pattern 612a may be different from the level of a voltage applied to the second conductive pattern 614a. The capacitor structure 600 may store charges in a first dielectric film 632 by using a potential difference between the first conductive pattern 612a and the second conductive pattern 614a. Similarly, different levels of voltage may be respectively applied to the second conductive pattern 614a and the third conductive pattern 616a, and accordingly, the capacitor structure 600 may store charges in a second dielectric film 634 by using a potential difference between the second conductive pattern 614a and the third conductive pattern 616a. The first to fourth conductive patterns 612a, 614a, 616a, and 618a may include the same material as one another. For example, the first to fourth conductive patterns 612a, 614a, 616a, and 618a may include Co, Ti, Ni, W, Mo, a TiN film, a TiSiN film, a TiAlN film, a TaN film, a TaSiN film, a TaAlN film, a WN film, or a combination thereof, but embodiments are not limited thereto.

The area of the top surface of each of the first to fourth conductive patterns 612a, 614a, 616a, and 618a may increase toward the substrate 100. For example, the area of the top surface of the third conductive pattern 616a may be greater than the area of the top surface of the fourth conductive pattern 618a, the area of the top surface of the second conductive pattern 614a may be greater than the area of the top surface of the third conductive pattern 616a, and the area of the top surface of the first conductive pattern 612a may be greater than the area of the top surface of the second conductive pattern 614a.

The capacitor structure 600 may further include first to third dielectric films 632, 634, and 636 among the first to fourth conductive patterns 612a, 614a, 616a, and 618a. The first dielectric film 632 may be between the top surface of the first conductive pattern 612a and the bottom surface of the second conductive pattern 614a and may extend along the top surface of the first conductive pattern 612a. The second dielectric film 634 may be between the top surface of the second conductive pattern 614a and the bottom surface of the third conductive pattern 616a and may extend along the top surface of the second conductive pattern 614a. The third dielectric film 636 may be between the top surface of the third conductive pattern 616a and the bottom surface of the fourth conductive pattern 618a and may extend along the top surface of the third conductive pattern 616a. For example, the first to third dielectric films 632, 634, and 636 may include at least one of silicon nitride, silicon oxide, and a combination thereof but are not limited thereto. For example, the first to third dielectric films 632, 634, and 636 may include a high-k material that has a higher permittivity than silicon oxide.

According to an embodiment, the area of the top surface of each dielectric film of the first to third dielectric films 632, 634, and 636 may be substantially the same as the area of the bottom surface of one conductive pattern of the first to fourth conductive patterns 612a. 614a, 616a, and 618a which is on the each dielectric film. For example, as shown in FIG. 10B, the area of the top surface of the first dielectric film 632 may be substantially the same as the area of the bottom surface of the second conductive pattern 614a on the first dielectric film 632. The area of the top surface of the second dielectric film 634 may be substantially the same as the area of the bottom surface of the third conductive pattern 616a on the second dielectric film 634. The area of the top surface of the third dielectric film 636 may be substantially the same as the area of the bottom surface of the fourth conductive pattern 618a on the third dielectric film 636. Because the area of the top surface of each of the first to third dielectric films 632, 634, and 636 may be substantially the same as the area of the bottom surface of one conductive pattern of the second to fourth conductive patterns 614a. 616a, and 618a, which is on the each dielectric film 632, 634, or 636, the top surface of each of the first to third dielectric films 632, 634, and 636 may be not exposed to the outside.

The capacitor structure 600 may include a first via 662 at a side thereof. The first via 662 may extend through the interlayer insulating film 652 in the third direction (e.g., the z-direction) that is perpendicular to the top surface of the lower insulating film 112. As shown in FIG. 10B, the capacitor structure 600 may have a sandwich shape, in which layers having different areas are sequentially stacked. In embodiments, the first via 662 may be on a side of the sandwich shape of the capacitor structure 600. The capacitor structure 600 may include a second via 672 at a side which is opposite to the side in which the first via 662 is provided. The second via 672 may extend through the interlayer insulating film 652 in the third direction (e.g., the z-direction) that is perpendicular to the top surface of the lower insulating film 112.

As shown in FIG. 10C, the first via 662 may be in physical contact with and electrically connected to the first conductive pattern 612a and the third conductive pattern 616a. However, the first via 662 may be not in physical contact with the second conductive pattern 614a and the fourth conductive pattern 618a, and may thus be insulated from the second conductive pattern 614a and the fourth conductive pattern 618a. For example, at least a portion of the top surface of the first conductive pattern 612a may be not in contact with the first dielectric film 632. For example, the first conductive pattern 612a may include a portion which is in contact with the first via 662, and a portion which is in contact with the first dielectric film 632, on the top surface thereof. In embodiments, the first conductive pattern 612a may be electrically connected to the first via 662 through the portion that is in contact with the first via 662.

The first dielectric film 632 may extend along the top surface of the first conductive pattern 612a. A side of the first dielectric film 632, which is near the second via 672, may be on the same vertical line as a side of the first conductive pattern 612a, which is near the second via 672. Accordingly, the top surface of the first conductive pattern 612a may be not in contact with the second via 672 and may thus be insulated from the second via 672. The third conductive pattern 616a may be similarly electrically connected to the first via 662 and insulated from the second via 672.

For example, the first via 662 may be in contact with at least a portion of the top surface of the third conductive pattern 616a. The third conductive pattern 616a may include a portion which is in contact with the first via 662, and a portion which is in contact with the third dielectric film 636, on the top surface thereof. In embodiments, the third conductive pattern 616a may be electrically connected to the first via 662 through the portion that is in contact with the first via 662.

The second via 672 may be in physical contact with and electrically connected to the second conductive pattern 614a and the fourth conductive pattern 618a. The second via 672 may be not in physical contact with the first conductive pattern 612a and the third conductive pattern 616a and may thus be not electrically connected to the first conductive pattern 612a and the third conductive pattern 616a. For example, the second conductive pattern 614a may include a portion which is in contact with the second via 672, and a portion which is in contact with the second dielectric film 634, on the top surface thereof. In embodiments, the second conductive pattern 614a may be electrically connected to the second via 672 through the portion that is in contact with the second via 672.

The second dielectric film 634 may extend along the top surface of the second conductive pattern 614a. A side of the second dielectric film 634, which is near the first via 662, may be on the same vertical line as a side of the second conductive pattern 614a, which is near the first via 662. Accordingly, the top surface of the second conductive pattern 614a may be not in contact with the first via 662 and may thus be insulated from the first via 662. The second conductive pattern 614a may be similarly electrically connected to the second via 672 and insulated from the first via 662.

For example, the second via 672 may be in contact with at least a portion of the top surface of the fourth conductive pattern 618a. The fourth conductive pattern 618a may include a portion which is in contact with the second via 672, and a portion which is in contact with the dielectric film on the top surface thereof. In embodiments, the fourth conductive pattern 618a may be electrically connected to the second via 672 through the portion that is in contact with the second via 672.1

Accordingly, as described above, the integrated circuit device 20 may include the capacitor structure 600 including the first conductive pattern 612a, the second conductive pattern 614a, the third conductive pattern 616a, and the fourth conductive pattern 618a, which are sequentially stacked on a plane. The capacitor structure 600 may store a high capacity of charge in a limited space by including the first to fourth conductive patterns 612a, 614a, 616a, and 618a that are sequentially stacked.

According to an embodiment, the first conductive pattern 612a and the third conductive pattern 616a may be electrically connected to one first via 662, and the second conductive pattern 614a and the fourth conductive pattern 618a may be electrically connected to one second via 672. Because the first conductive pattern 612a and the third conductive pattern 616a may be electrically connected to one another by the first via 662, and not by separate vias, and the second conductive pattern 614a and the fourth conductive pattern 618a may be electrically connected to one another by the second via 672, and not by separate vias, each conductive pattern may quickly and efficiently transmit electrical signals to another element.

As shown in FIGS. 10B and 10C, a side wall of each of the first via 662 and the second via 672, which faces the first to fourth conductive patterns 612a, 614a, 616a, and 618a, may have a stair shape. For example, the side wall of each of the first via 662 and the second via 672 may include a horizontal surface, which is in contact with one of the first to fourth conductive patterns 612a, 614a, 616a, and 618a, and a vertical surface, which is in contact with a side wall of one of a plurality of insulating spacers 642. An opposite side wall facing away from the side wall of each of the first via 662 and the second via 672 may decline toward the first to fourth conductive patterns 612a, 614a. 616a, and 618a. The horizontal cross-sectional area of each of the first via 662 and the second via 672 may non-linearly decrease toward the substrate 100. For example, the horizontal cross-sectional area of each of the first via 662 and the second via 672 at the same vertical level as the top surface of each of the first to fourth conductive patterns 612a, 614a, 616a, and 618a may rapidly decrease toward the substrate 100.

A first wiring 664 may be on the interlayer insulating film 652, and a second wiring 674 may be spaced horizontally apart from the first wiring 664. The first wiring 664 may cover a portion of the interlayer insulating film 652 and may be electrically connected to the first via 662. The second wiring 674 may cover a portion of the interlayer insulating film 652 and may be electrically connected to the second via 672. The first wiring 664 may overlap with a portion of the first conductive pattern 612a and a portion of the third conductive pattern 616a, and the second wiring 674 may overlap with a portion of the second conductive patterns 614a and a portion of the fourth conductive pattern 618a.

According to an embodiment, the capacitor structure 600 may include an insulating spacer 642 surrounding, covering, or in contact with a side wall of at least one of the first to fourth conductive patterns 612a, 614a, 616a, and 618a. A side wall of the insulating spacer 642 may be in contact with at least one of the first to fourth conductive patterns 612a, 614a, 616a, and 618a. An opposite side wall of the insulating spacer 642, which faces away from the side wall discussed above, may be in contact with the first via 662 or the second via 672. Because the insulating spacer 642 may be formed to surround the side wall of at least one of the first to fourth conductive patterns 612a, 614a, 616a, and 618a, the first conductive pattern 612a and the third conductive pattern 616a may be not in contact with the second via 672, and the second conductive pattern 614a and the fourth conductive pattern 618a may be not in contact with the first via 662. The insulating spacer 642 may include silicon nitride or silicon oxide but is not necessarily limited thereto.

Other conductive patterns 612b, 614b, 616b, and 618b may be stacked on the fourth conductive pattern 618a in the third direction (e.g., the z-direction), wherein the conductive patterns 612b, 614b, 616b, and 618b may be spaced apart from one another. The functions of the conductive patterns 612b. 614b, 616b, and 618b and the dielectric films 632 may be substantially the same as, or similar to, those of the first to fourth conductive patterns 612a, 614a. 616a, and 618a and the first to third dielectric films 632, 634, and 636, which form a lower portion of the capacitor structure 600. The odd-numbered conductive patterns 612b and 616b (counting from the bottom among the conductive patterns 612b, 614b, 616b, and 618b) may be in physical contact with and electrically connected to the first via 662, and may be not in physical contact with, and thus be insulated from, the second via 672. The even-numbered conductive patterns 614b and 618b (counting from the bottom among the conductive patterns 612b, 614b, 616b, and 618b) may be in physical contact with and electrically connected to the second via 672, and may be not in physical contact with, and thus be insulated from, the first via 662.

The upper insulating film 700 may be on the interlayer insulating film 652. In embodiments, other elements may be formed in the upper insulating film 700 and may be electrically connected to the capacitor structure 600.

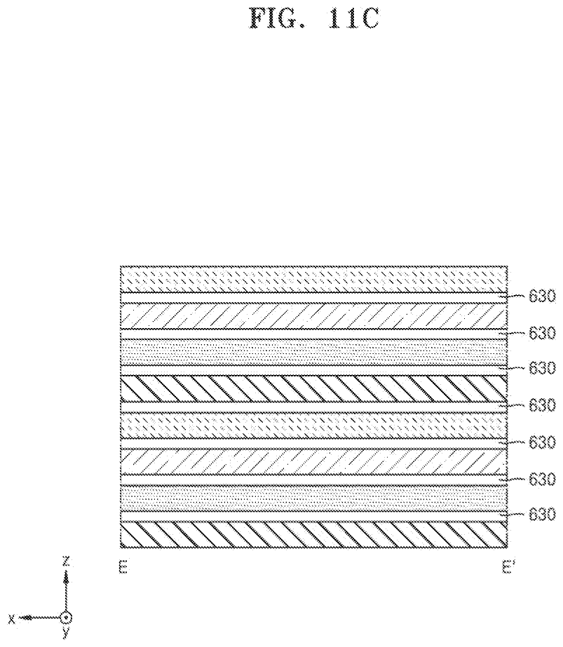

FIGS. 11A to 17C are cross-sectional views of some stages in a method of manufacturing the integrated circuit device 20 of FIG. 10A. For example, FIGS. 11B, 12B, 13B, 14B, 15B, 16B and 17B are cross-sectional views taken along line D-D′, and FIGS. 11C, 12C, 13C, 14C, 15C, 16C and 17C are cross-sectional views taken along line E-E′.

Referring to FIGS. 11A to 11C, a plurality of conductive layers 610 may be stacked on and spaced apart from each other in the third direction (e.g., the z-direction). A dielectric layer 630 may be between two adjacent conductive layers 610.

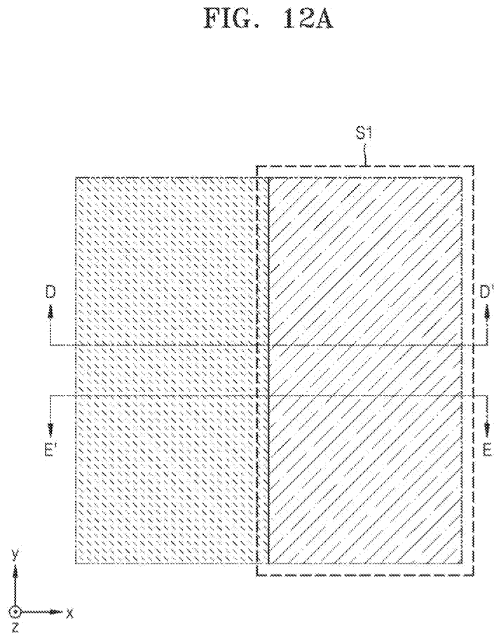

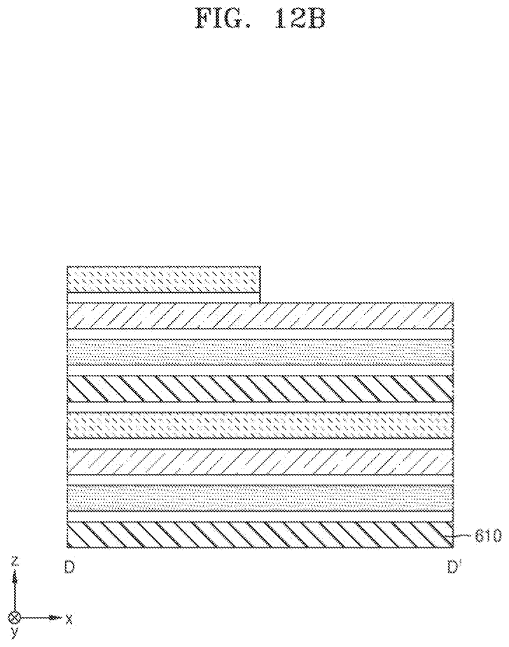

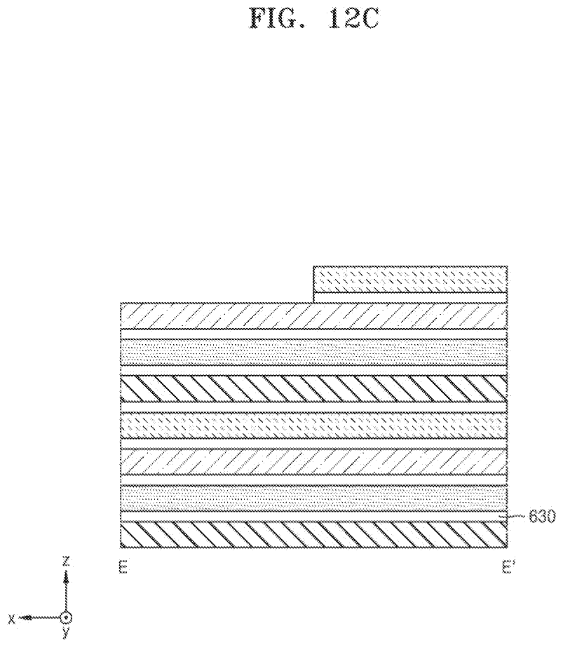

Referring to FIGS. 12A to 12C, a portion of a topmost conductive layer 610 may be etched. A mask may be disposed on a left portion of the top surface of the topmost conductive layer 610 in the first direction (e.g., the x-direction), and a right portion S1 of the topmost conductive layer 610 may be etched. In embodiments, the topmost conductive layer 610 and one dielectric layer 630 may be etched. When the right portion S1 of the topmost conductive layer 610 is etched, a portion of the top surface of a conductive layer 610 below the topmost conductive layer 610 may be exposed.

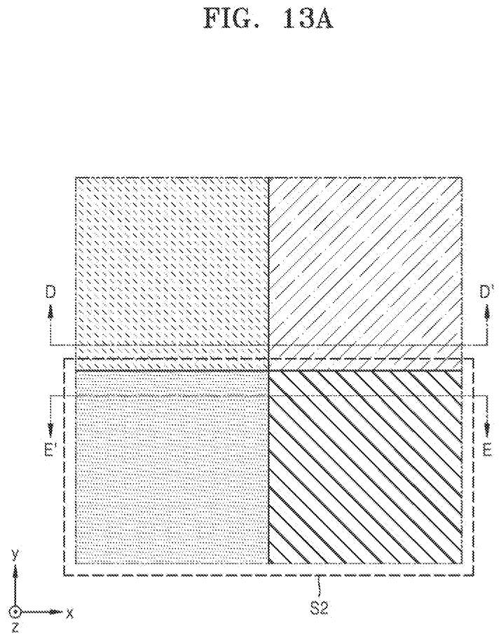

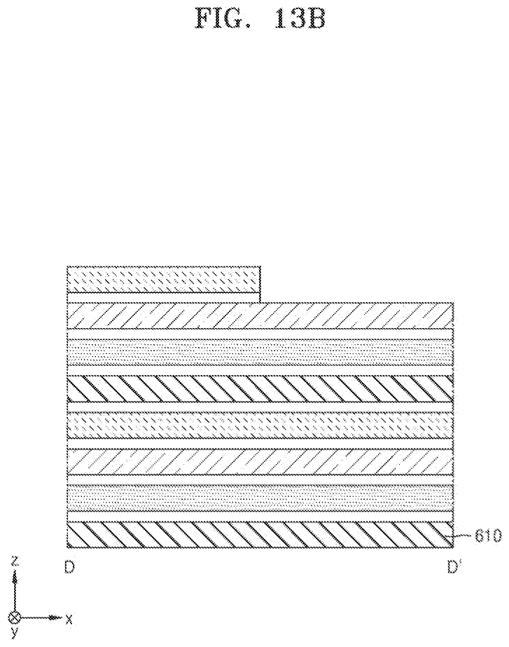

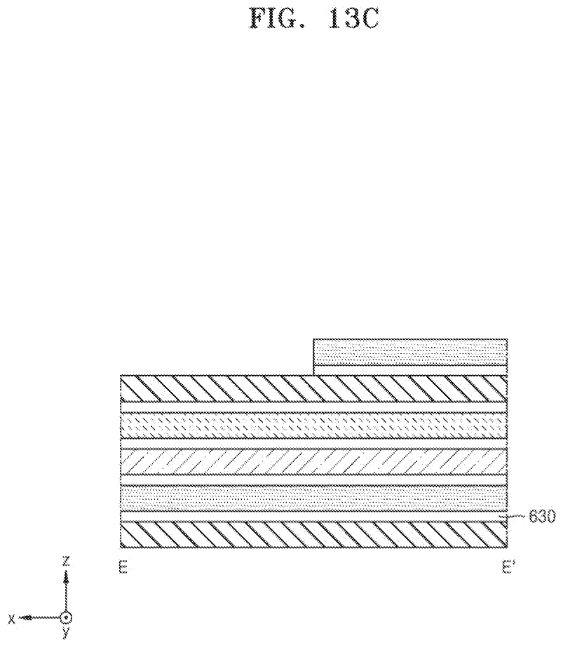

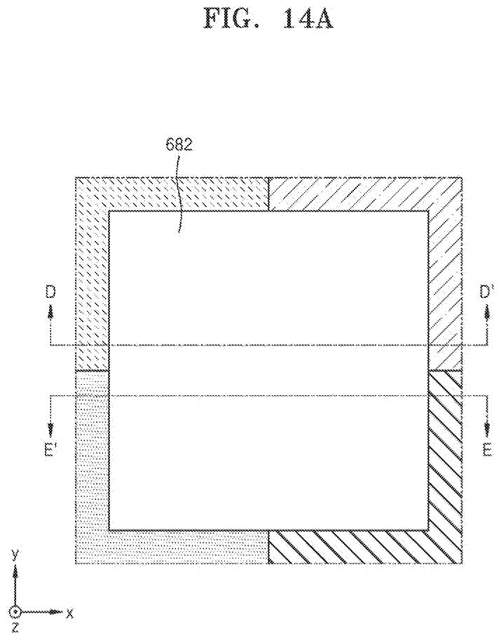

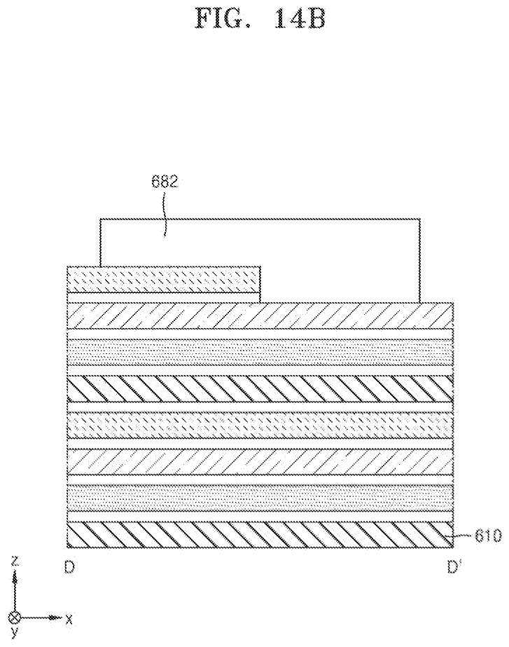

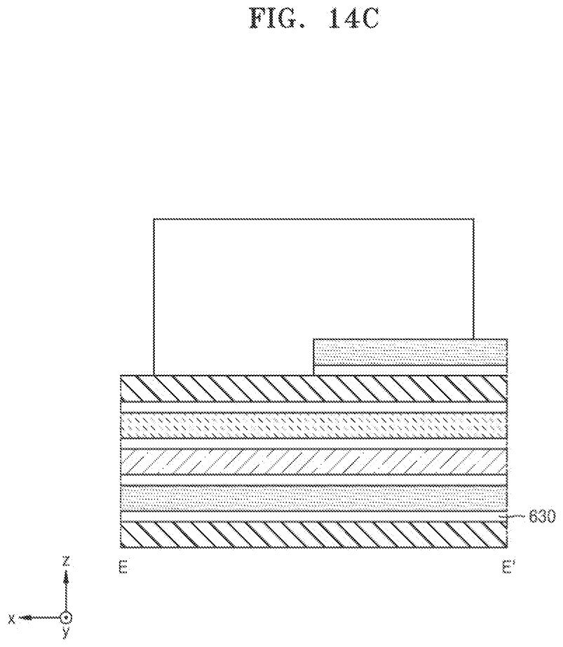

Referring to FIGS. 13A to 13C, portions of second and third conductive layers 610, counting from the top in the third direction (e.g., the z-direction), may be etched. A mask may be disposed on an upper portion in the second direction (e.g., the y-direction) in FIG. 13A, and a lower portion S2 in the second direction (e.g., the y-direction) may be etched. In embodiments, two conductive layers 610 and two dielectric layers 630 may be etched. Accordingly, the respective top surfaces of third and fourth conductive layers 610 (counting from the top in the third direction (e.g., the z-direction)) may be partially exposed.

Referring to FIGS. 14A to 14C, a mask 682 may be disposed on top surfaces of a plurality of conductive layers 610. The area of the top surface of the mask 682 may be smaller than the area of the top surface of a bottommost conductive layer 610. As illustrated in FIG. 14A, the center of the mask 682 coincides with the center of the stack structure of conductive layers 610, but embodiments are not limited thereto. For example, according to embodiments, the center of the mask 682 may not coincide with the center of the stack structure of conductive layers 610.

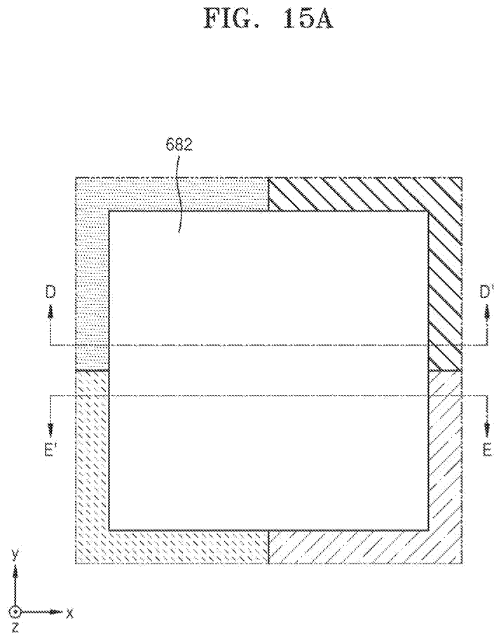

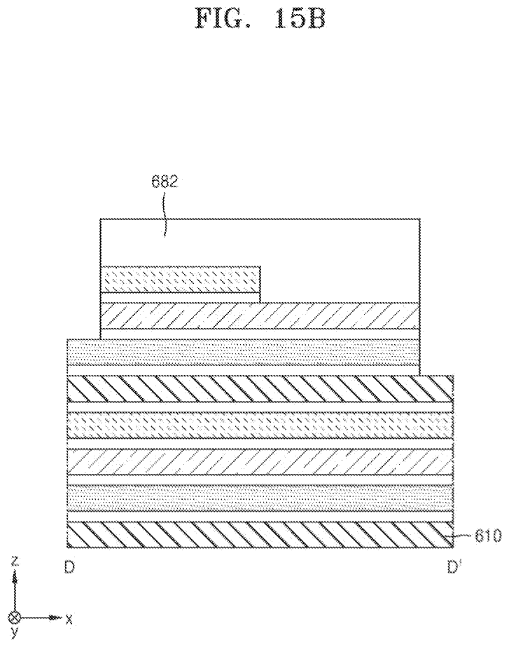

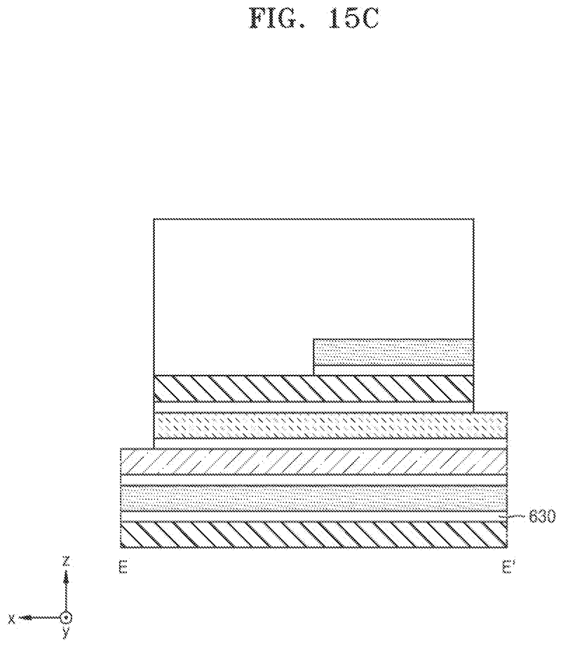

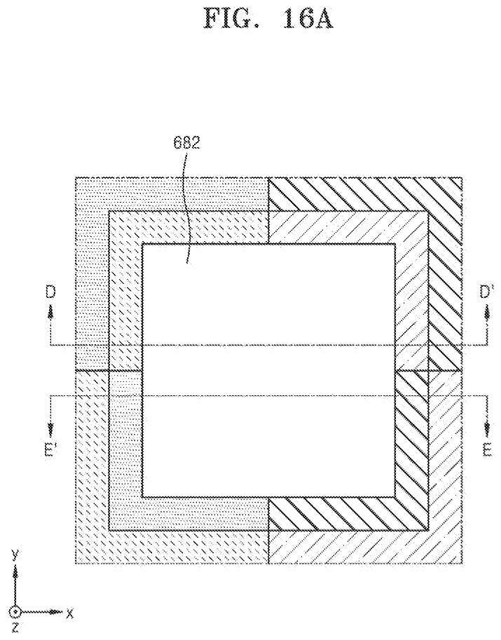

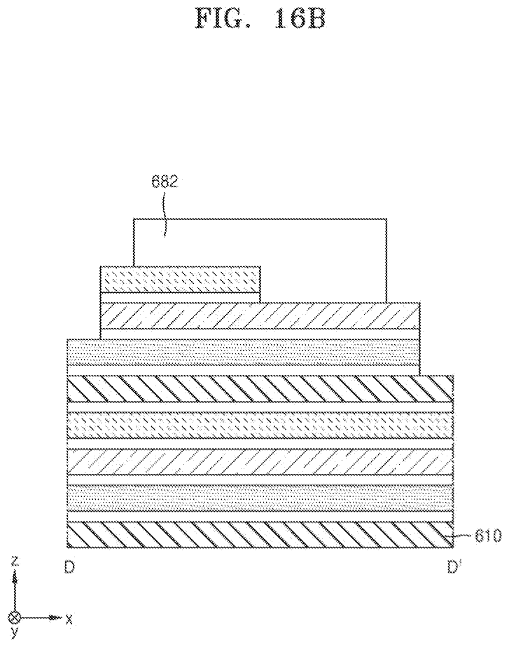

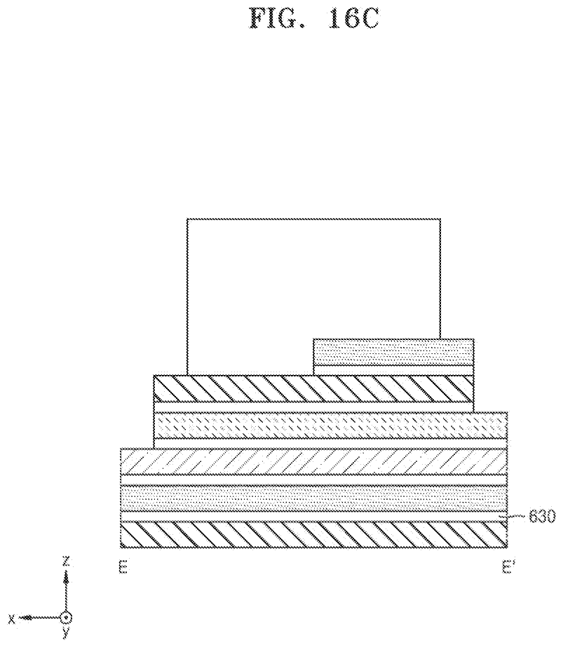

Referring to FIGS. 15A to 15C, a plurality of conductive layers 610 and a plurality of dielectric layers 630 may be etched. In embodiments, portions of the conductive layers 610 and the dielectric layers 630, which are not covered by the mask 682, may be etched. As shown in FIGS. 15B and 15C, two conductive layers 610 and two dielectric layers 630 may be etched.

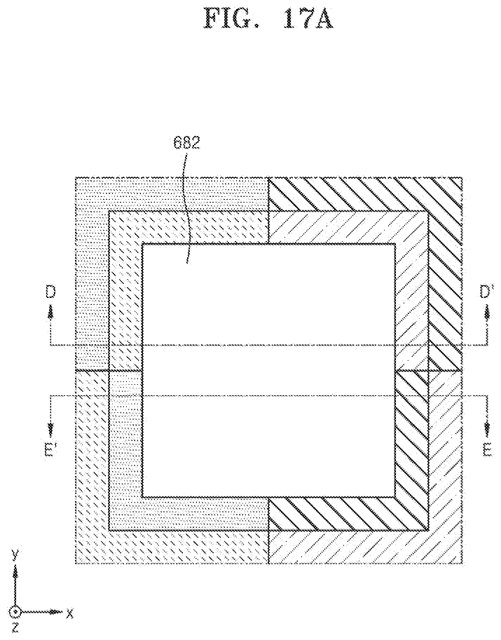

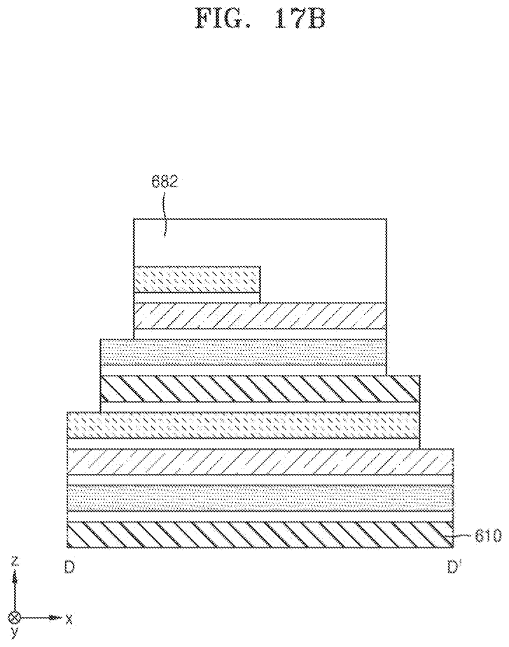

Referring to FIGS. 16A to 16C, an edge portion of the mask 682 may be etched. According to an embodiment, a series of etching processes may be performed on the conductive layers 610 by using and etching a single mask pattern instead of using various mask patterns. Accordingly, etching processes may be efficiently performed at reduced cost.

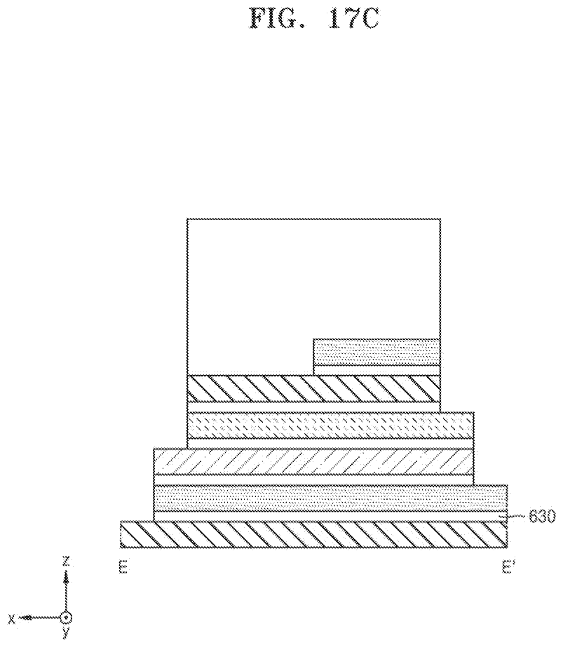

Referring to FIGS. 17A to 17C, a plurality of conductive layers 610 and a plurality of dielectric layers 630 may be etched. Portions of the conductive layers 610 and the dielectric layers 630, which are not covered by the mask 682, may be etched. As shown in FIGS. 17B and 17C, two conductive layers 610 and two dielectric layers 630 may be etched. Accordingly, portions of odd-numbered conductive layers 610 counting from the bottom, which are at a side in the first direction (e.g., the x-direction) of the stack structure of conductive layers 610, may be exposed. Portions of even-numbered conductive layers 610 counting from the bottom, which are at an opposite side in the first direction (e.g., the x-direction) of the stack structure of conductive layers 610, the opposite side facing the above one side of the stack structure of conductive layers 610, may be exposed. Thereafter, the mask 682 may be removed, and a via may be formed at a side of the stack of the conductive layers 610.

While embodiments have been particularly shown and described with reference to the drawings, it will be understood that various changes in form and details may be made therein without departing from the spirit and scope of the following claims.

What is claimed is:

1. An integrated circuit device comprising:
a substrate;
a lower insulating film on the substrate, the lower insulating film comprising a device; and
a capacitor structure on the lower insulating film,
wherein the capacitor structure comprises:
a plurality of first conductive patterns sequentially stacked on the lower insulating film and spaced apart from each other;
a plurality of second conductive patterns on the plurality of first conductive patterns and spaced apart from each other, wherein each second conductive pattern of the plurality of second conductive patterns is on a corresponding first conductive pattern of the plurality of first conductive patterns;
a first via at a first side of the capacitor structure, wherein the first via physically contacts and is electrically connected to the plurality of first conductive patterns, and is not electrically connected to the plurality of second conductive patterns; and
a second via at a second side of the capacitor structure, wherein the second side is opposite to the first side and faces the first side, and wherein the second via physically contacts and is electrically connected to the plurality of second conductive patterns, and is not electrically connected to the plurality of first conductive patterns.

2. The integrated circuit device of claim 1, wherein the first via is not in physical contact with the plurality of second conductive patterns, and
wherein the second via does not physically contact the plurality of first conductive patterns.

3. The integrated circuit device of claim 1, wherein the capacitor structure further includes a plurality of insulating spacers at side walls of the plurality of first conductive patterns and side walls of the plurality of second conductive patterns,
wherein each insulating spacer of the plurality of insulating spacers comprises:
a first side wall contacting at least one conductive pattern of the plurality of first conductive patterns and the plurality of second conductive patterns, and
a second side wall contacting one via from among the first via and the second via, wherein the second side wall is opposite to the first side wall.

4. The integrated circuit device of claim 3, wherein the plurality of insulating spacers comprises a first insulating spacer contacting the first via and a second insulating spacer contacting the second via, and
wherein a level of a top surface of the first insulating spacer different from a level of a top surface of the second insulating spacer.

5. The integrated circuit device of claim 1, wherein a horizontal cross-sectional area of each of the first via and the second via non-linearly decreases in a direction toward the substrate.

6. The integrated circuit device of claim 1, wherein a first side wall of each of the first via and the second via faces the plurality of first conductive patterns and the plurality of second conductive patterns, and has a stair shape.

7. The integrated circuit device of claim 6, wherein a second side wall of each of the first via and the second via declines in a direction toward the plurality of first conductive patterns and the plurality of second conductive patterns, and
wherein the second side wall is opposite to the first side wall and faces away from the first side wall.

8. The integrated circuit device of claim 1, wherein the capacitor structure further comprises a dielectric film between a first conductive pattern of the plurality of first conductive patterns and a second conductive pattern of the plurality of second conductive patterns,
wherein a conductive pattern from among the first conductive pattern and the second conductive pattern is on the dielectric film, and
wherein an area of a top surface of the dielectric film is substantially equal to an area of a bottom surface of the conductive pattern.

9. The integrated circuit device of claim 1, wherein the capacitor structure further comprises:
a first dielectric film on a first conductive pattern of the plurality of first conductive patterns,
a second conductive pattern of the plurality of second conductive patterns, wherein the second conductive pattern is on the first dielectric film; and
a second dielectric film on the second conductive pattern,
wherein a top surface of the first conductive pattern comprises a first portion contacting the first via and a second portion contacting the first dielectric film, and
wherein a top surface of the second conductive pattern comprises a third portion contacting the second via and a fourth portion contacting the second dielectric film.

10. The integrated circuit device of claim 1, further comprising:
a first wiring horizontally extending on the first via, the first wiring contacting the first via and having a first horizontal cross-sectional area which is wider than the first via; and
a second wiring horizontally extending on the second via, the second wiring contacting the second via and having a second horizontal cross-sectional area which is wider than the second via,
wherein the first wiring overlaps a portion of each of the plurality of first conductive patterns, and
the second wiring overlaps a portion of each of the plurality of second conductive patterns.

11. An integrated circuit device comprising:
a substrate;
a lower insulating film on the substrate, the lower insulating film comprising a device; and
a capacitor structure on the lower insulating film,
wherein the capacitor structure comprises:
a first conductive pattern on the lower insulating film;
a second conductive pattern on the first conductive pattern;
a third conductive pattern on the second conductive pattern;
a fourth conductive pattern on the third conductive pattern;
a first via at a first side of the capacitor structure, wherein the first via being physically contacts and is electrically connected to the first conductive pattern and the third conductive pattern, and is not electrically connected to the second conductive pattern and the fourth conductive pattern; and
a second via at a second side of the capacitor structure, wherein the second side is opposite to the first side and faces the first side, and wherein the second via physically contacts and is electrically connected to the second conductive pattern and the fourth conductive pattern and is not electrically connected to the first conductive pattern and the third conductive pattern.

12. The integrated circuit device of claim 11, wherein the first via does not physically contact the second conductive pattern and the fourth conductive pattern, and
the second via does not physically contact the first conductive pattern and the third conductive pattern.

13. The integrated circuit device of claim 11, wherein the capacitor structure further comprises a plurality of insulating spacers at a side wall of at least one of the first conductive pattern, the second conductive pattern, the third conductive pattern, and the fourth conductive pattern,
wherein each insulating spacer of the plurality of insulating spacers comprises:
a first side wall contacting the at least one of the first conductive pattern, the second conductive pattern, the third conductive pattern, and the fourth conductive pattern, and
a second side wall contacting one via from among the first via and the second via, wherein the second side wall is opposite to the first side wall.

14. The integrated circuit device of claim 11, wherein a horizontal cross-sectional area of each of the first via and the second via non-linearly decreases in a direction toward the substrate.

15. The integrated circuit device of claim 11, wherein the capacitor structure further comprises:
a first dielectric film between the first conductive pattern and the second conductive pattern;
a second dielectric film between the second conductive pattern and the third conductive pattern; and
a third dielectric film between the third conductive pattern and the fourth conductive pattern,
wherein an area of a top surface of the first dielectric film is substantially equal to an area of a bottom surface of the second conductive pattern,
wherein an area of a top surface of the second dielectric film is substantially equal to an area of a bottom surface of the third conductive pattern, and
wherein an area of a top surface of the third dielectric film is substantially equal to an area of a bottom surface of the fourth conductive pattern.

16. The integrated circuit device of claim 11, further comprising:
a first wiring horizontally extending on the first via, the first wiring contacting the first via and having a first horizontal cross-sectional area which is wider than the first via; and
a second wiring horizontally extending on the second via, the second wiring contacting the second via and having a second horizontal cross-sectional area which is wider than the second via,
wherein the first wiring overlaps a portion of the first conductive pattern and a portion of the third conductive pattern, and
the second wiring overlaps a portion of the second conductive pattern and a portion of the fourth conductive pattern.

17. The integrated circuit device of claim 11, wherein an area of a top surface of the first conductive pattern is larger than an area of a top surface of the second conductive pattern,
wherein the area of the top surface of the second conductive pattern is larger than an area of a top surface of the third conductive pattern, and
wherein the area of the top surface of the third conductive pattern is larger than an area of a top surface of the fourth conductive pattern.

18. The integrated circuit device of claim 11, wherein each of the first conductive pattern, the second conductive pattern, the third conductive pattern, and the fourth conductive pattern comprises at least one from among cobalt (Co), titanium (Ti), nickel (Ni), tungsten (W), molybdenum (Mo), a titanium nitride (TiN) film, a titanium silicon nitride (TiSiN) film, a titanium aluminum nitride (TiAlN) film, a tantalum nitride (TaN) film, a tantalum silicon nitride (TaSiN) film, a tantalum aluminum nitride (TaAlN) film, a tungsten nitride film (WN) film.

19. An integrated circuit device comprising:
a substrate;
a lower insulating film on the substrate, the lower insulating film comprising a device; and
a capacitor structure on the lower insulating film,
wherein the capacitor structure comprises:
a plurality of first conductive patterns sequentially stacked on the lower insulating film and spaced apart from each other;
a plurality of second conductive patterns on the plurality of first conductive patterns and spaced apart from each other, wherein each second conductive pattern of the plurality of second conductive patterns is on a corresponding first conductive pattern of the plurality of first conductive patterns;
a first via at a first side of the capacitor structure, wherein the first via physically contacts and is electrically connected to the plurality of first conductive patterns, and does not physically contact and is insulated from the plurality of second conductive patterns; and
a second via at a second side of the capacitor structure, wherein the second side is opposite to the first side and faces the first, and wherein the second via physically contacts and is electrically connected to the plurality of second conductive patterns, and does not physically contact and is insulated from the plurality of first conductive patterns,
wherein a horizontal cross-sectional area of each of the first via and the second via non-linearly decreases in a direction toward the substrate,
wherein a first side wall of each of the first via and the second via faces the plurality of first conductive patterns and the plurality of second conductive patterns and has a stair shape,
wherein a second side wall of each of the first via and the second via declines in a direction toward the plurality of first conductive patterns and the plurality of second conductive patterns, and
wherein the second side wall is opposite to the first side wall and faces away from the first side wall.

20. The integrated circuit device of claim 19, wherein the capacitor structure further includes:
a plurality of insulating spacers at side walls of the plurality of first conductive patterns and side walls of the plurality of second conductive patterns; and
a dielectric film between a first conductive pattern of the plurality of first conductive patterns and a second conductive pattern of the plurality of second conductive patterns,
wherein each insulating spacer of the plurality of insulating spacers comprises:
a first spacer side wall contacting at least one conductive pattern of the plurality of first conductive patterns and the plurality of second conductive patterns,
a second spacer side wall contacting one via from among the first via and the second via, wherein the second spacer side wall is opposite to the first spacer side wall,
wherein a conductive pattern from among the first conductive pattern and the second conductive pattern is on the dielectric film, and
wherein an area of a top surface of the dielectric film is substantially equal to an area of a bottom surface of the conductive pattern.
